(19) United States
(12) Patent Application Publication
(10) Pub. No.: US 2006/0097791 A1
(43) Pub. Date: May 11, 2006

(54) Low offset rail-to-rail operational amplifier

(76) Inventors: Robert Luckett Shuler JR., Friendswood, TX (US); R. Scott Askew, Houston, TX (US)

Correspondence Address: Robert Shuler, 5238 Appleblossom Lane, Friendswood, TX, 77546, US

(21) Appl. No.: 10/985,537

(22) Filed: Nov. 10, 2004

(51) Int. Cl. H03F 1/14

(52) U.S. Cl. 330/292

(57) ABSTRACT

An operational amplifier with a first stage differential input circuit having low aspect ratio devices of size chosen to achieve a low offset voltage, and an output stage having high aspect ratio devices able to operate at higher frequencies than the input stage, provides an amplifier with low static offset and requiring only a small compensation circuit due to the wide separation of frequency response poles. Adding a third stage gives a high gain design that can be stabilized with nested miller compensation. Adding a second differential input circuit of the same type as the first, and a level shifter, provides rail-to-rail operation without disturbing the low offset properties.

### BACKGROUND OF THE INVENTION

This invention relates generally to the field of integrated electronic circuits and more specifically to low offset rail-to-rail operational amplifiers.

Operational amplifiers having a differential input and a large gain are an essential building block of many electronics circuits. The offset of the amplifier is that voltage difference between the positive and negative input terminals which is interpreted as zero difference by the amplifier. In a properly designed circuit, the small residual offset results from unavoidable imperfections in the devices from which the amplifier input stage is made. The input common mode range (CMR) of the amplifier refers to the range of the average of the two input voltages over which the amplifier will operate. Basic amplifier designs will usually stop working if both input voltages approach one or the other of the input supply voltages (rails).

Bipolar junction transistor technology allows construction of amplifiers with low offset, but bipolar transistors have finite input impedance and add significant cost as compared with complementary metallic oxide semiconductor (CMOS) technology, which is very economical in bulk and provides near infinite input impedance. The industry rule-of-thumb guide is that offset of CMOS operational amplifiers usually cannot be guaranteed to be less than about five millivolts, and is highly variable from one amplifier to another. This creates inaccuracies in the tens or hundreds of percent when dealing with low-level signals. Also, many circuits have the unfortunate effect of multiplying the input offset by gain or some other large factor.

The most fundamental method of reducing offset is to use a symmetrically balanced circuit with identical topology and devices for each of the differential inputs, plus (non-inverting) and minus (inverting). FIG. 1 shows a basic operational amplifier according to prior art, with an input stage 101, and an output stage 104. The differential input 102 typically consists of a matched pair of transistors M1 and M2 having identical channel (gate) width and length. The bias current provided by M7 splits evenly between M1 and M2 when the voltages at input nodes plus and minus are identical. The current mirror 103 consists of another matched pair of transistors M3 and M4, which combine the currents through M1 and M2 at node 106 producing a voltage that drives the output stage.

In order to prevent the amplifier of FIG. 1 from oscillating when used with feedback, a stability compensation circuit 105 is provided which connects from the output node vout to the input of the output stage node 106. This is called a Miller capacitor. It takes advantage of the gain of the stage or stages around which it is connected to magnify its effect. Other more complex compensation circuits can be used, for example a resistor is often connected in series with the Miller capacitor. For other schemes see Huijsing (U.S. Pat. No. 5,485,121) and Aude (U.S. Pat. No. 6,580,325 B1). In switched amplifiers charging and discharging this Miller capacitor degrades performance, which is addressed with two capacitors by Ausserlechner (U.S. Pat. No. 6,621,334 B2). If more than two gain stages are present, ordinary Miller compensation may not be sufficient. A multi-stage compensation scheme for four or more stages, an even number of them, is given by Huijsing (U.S. Pat. No. 5,486,790).

Mismatch in the pairs of transistors will produce offset, such that identical voltages at plus and minus will not result in identical currents through M1 and M2. Various techniques are used to produce good matching, including co-location and similar orientation of the devices being matched, elimination of effects from surrounding structures, and breaking the devices up into smaller pieces and arranging them according to certain symmetry rules (interdigitation). For an example of matching see Nakamura (U.S. Pat. No. 5,767,542).

In addition to identical matched pairs, scaled matching relations exist among all the other transistors such that currents are at fixed multiples. For example, for a zero differential input the currents through M5 and M6 must be identical in order to avoid offset. The designer usually makes the channel lengths of all the transistors the same, and adjusts the channel width to perform scaled matching. A transistor twice as wide, under otherwise identical conditions, will carry twice the current. So the designer will decide how much output bias current is desired, and scale M6 relative to M7 to achieve this. Then M5 is scaled twice as much relative to M4, since M4 carries half the current of M7. M7 is sized relative to M8, which carries the same bias current as M9 set by the supplied bias voltage.

Tradeoffs exist between optimal matching and other amplifier properties. Mismatch can result from small differences in the actual geometry of supposedly identical devices, or from differences in the electrical properties of the region in which the device is fabricated. According to Lovett et. al. in “Optimizing MOS Transistor Mismatch”(IEEE Journal of Solid-State Circuits, January 1998) channel length is more important in matching than width. However, making the channel too long results in a slow amplifier that is difficult to stability compensate, and results in the output transistors being unreasonably large due to scaled matching. Typical designs settle for an aspect ratio (ratio of channel width to length) in the normal range from about two to about ten for the matched pairs, and aspect ratios in the high range (greater than about ten) for the output transistors.

Methods are known to compensate for the offset that remains after matching techniques have been applied. Static methods include providing extra input terminals and correction voltages. Dynamic methods include several types of switching techniques. Choppers reverse the input connections periodically and average the result. Auto-zero amps use a capacitor in series with one of the inputs which is periodically charged up using a feedback circuit to exactly balance the offset voltage. Ping-pong amplifiers use multiple amplifiers switching back and forth such that when one is operating, the other is being auto-zeroed or otherwise measured and adjusted.

The basic amplifier of FIG. 1 is not a rail-to-rail amplifier. If both input voltages approach within about 0.7 volts of the positive supply rail, the source to gate voltage of transistors M1 and M2 will fall below the typical threshold voltage of 0.7 volts and the input stage will pinch off.

There are many known methods for designing operational amplifiers with rail-to-rail input common mode range. These include switching (charge pump) methods to produce a higher voltage internally, and multiple input methods. For an example of switching methods see Schaffer (U.S. Pat. No. 5,880,638).

The most common multiple-input methods use one input circuit that pinches off at one supply rail, and a second input circuit that pinches off at the other rail, with some method of combining the two inputs so that the amp operates over the entire range. For CMOS op amps, this usually means N-type field effect transistors (FET's) for one differential pair, and P-type FET's for the other. Such an amp is said to use complementary input pairs. For examples see Ling (U.S. Pat. No. 5,650,753), Bazes (U.S. Pat. No. 4,958,133), Badyal (U.S. Pat. No. 5,337,008), Juang (U.S. Pat. No. 5,917,378), Zhang (U.S. Pat. No. 5,929,705), Sauer (U.S. Pat. No. 5,959,498, in this case combined with a chopper), Basu (U.S. Pat. No. 6,031,423), Ivanov (U.S. Pat. Nos. 6,150,883 and 6,356,153 B1 and 6,462,619 B1), and Lin (U.S. Pat. No. 6,384,683 B1).

Lorenz (U.S. Pat. No. 6,384,679 B1) gives a complex scheme for rail to rail operation which tries to overcome some of the limitations of splicing together the outputs from the complementary inputs by monitoring one of the inputs (which he calls an amplifier) and using the result to control the bias of the second input (amplifier). However, Lorenz still uses complementary transistors in the two input amplifiers.

Dynamic (switched) offset reduction methods can be made to work very well, however they add a great deal of complexity and thus area. Generally they require dozens of milliamps or more of current to power each switched op amp. The power is required both directly for the charging and discharging of parasitic capacitances, and indirectly because switched amps have to be fast which is usually accomplished with higher bias currents. Great care must be taken with design and layout to avoid noise, and large circuit areas are normally required as compared with static op amps.

Rail-to-rail op amps of the higher voltage variety may violate the voltage limitations of a particular technology. Amps of the complementary input pair variety have the unfortunate effect that their input offset voltage varies over the common mode range, since the two input pairs will have different offset characteristics. The combining circuitry, which is invariably asymmetric, may further disturb offset characteristics. Thus the problems of low static offset and wide common mode range are linked.

The variability of offset with input common mode voltage implies that switching techniques that compensate offset must operate at a high rate compared with the rate of change of input common mode voltage. This means the amp must be made faster by using smaller and higher aspect ratio devices (ratio of channel width to length for FET's), which in turn increases the variability of offset with common mode voltage, and further pushes up the switching rate in a vicious cycle.

### BRIEF SUMMARY OF THE INVENTION

The primary object of the invention is to provide an operational amplifier possessing an inherently low offset not requiring static or dynamic offset compensation.

Another object of the invention is to provide a high gain operational amplifier not requiring excessive stability compensation.

Another object of the invention is to provide an operational amplifier responsive to rail-to-rail input common mode voltages while maintaining low offset variability over the common mode range.

A further object of the invention is to provide a simplified and auto-routable rail-to-rail operational amplifier with low offset.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed a low offset operational amplifier comprising: a first stage differential input circuit having low aspect ratio devices of size chosen to achieve a low offset voltage, an output stage having short channel high aspect ratio devices able to operate at higher speed than the input stage, a stability compensation circuit, whereby said operational amplifier will have low offset and a small compensation circuit.

In accordance with a preferred embodiment of the invention, there is disclosed a three stage operational amplifier with nested miller compensation comprising: a first stage differential input circuit, a second stage differential gain circuit, a third stage inverting output circuit, a first compensation circuit connected from the output of the amplifier to the input of the third stage, a second compensation circuit connected from the output of the amplifier to the inverting input of the second stage, whereby stability of the high gain amplifier is achieved with low area compensation circuit elements.

In accordance with a preferred embodiment of the invention, there is disclosed a rail to rail input common mode range amplifier comprising: an input voltage level shifting circuit, a first input stage differential pair, a second input stage differential pair of the same device type as the first input stage differential pair, a single input stage current mirror, whereby operation over a rail to rail input common mode range is obtained without bias elevation above a rail, an offset discontinuity in the center of the common mode range, or complex recombination circuitry.

### BRIEF DESCRIPTION OF THE DRAWINGS

The drawings constitute a part of this specification and include exemplary embodiments to the invention, which may be embodied in various forms. It is to be understood that in some instances various aspects of the invention may be shown in a circuit context to facilitate an understanding of the invention.

FIG. 1 is an electrical schematic of a basic operational amplifier according to prior art.

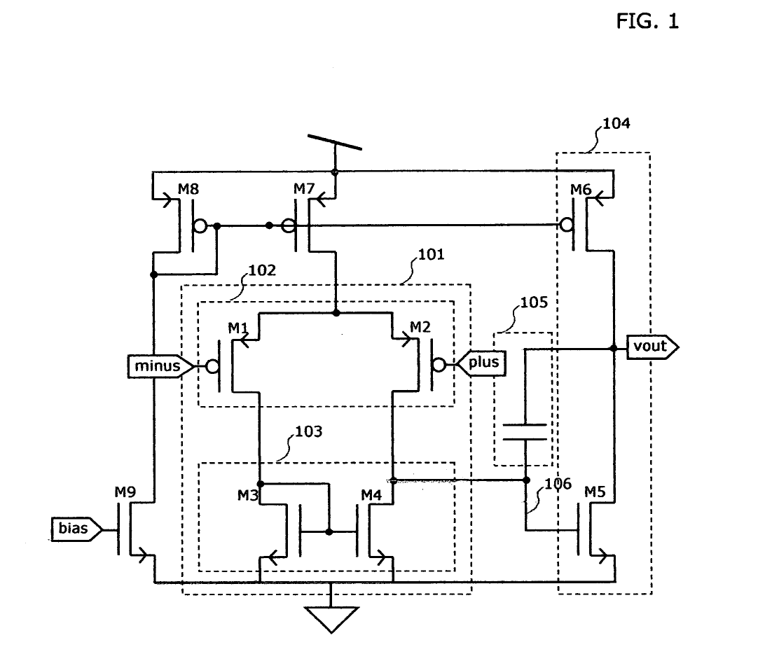

FIG. 2 is an electrical schematic of an operational amplifier with well-matched input according to the invention.

FIG. 3 is an electrical schematic of a three stage operational amplifier with nested miller compensation and progressive stage speed according to the invention.

FIG. 4 is an electrical schematic of a rail-to-rail operational amplifier with dual inputs and level shifter according to the invention.

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

Optimal Matching.

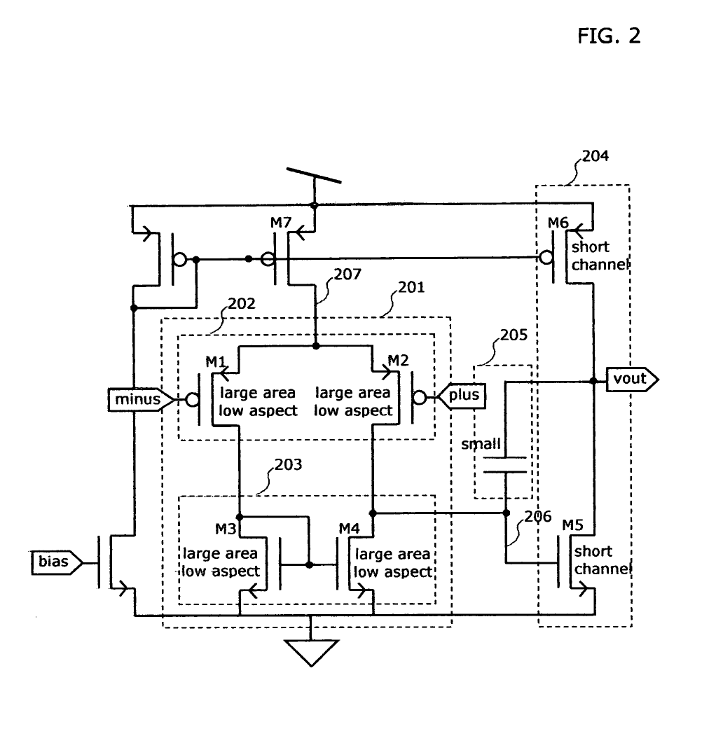

Turning first to FIG. 2, there is shown a low offset operational amplifier in accordance with the present invention. A first aspect is that the matched pair of field effect transistors M1 and M2 providing the differential input 202 are made larger in area and with a lower aspect ratio, less than about two, than in prior art. The results of Lovett mentioned previously apply to smaller transistors for which channel length modulation by the applied drain to source voltage is a factor. Of importance to the present invention is the discovery that for larger transistors geometric uncertainty of device dimensions is the dominant source of offset, and that geometric uncertainty is predictably related to the minimum feature size of the process used to fabricate the transistors. If one dimension of a transistor, length or width, is much larger than the other, then the smaller dimension determines the degree of mismatch. It follows from this that the most efficient use of area when drawing a large transistor for matching purposes is to make it approximately square, that is to give it a low aspect ratio of about one.

The differential input pair 202 together with the current mirror pair 203 form the input circuit 201. Computational (spice) modeling shows that matching of the differential input pair and of the current mirror pair each have a similar magnitude of effect on offset. The current mirror pair is made the same size as the differential input pair so that their contribution to offset is similar, and the total area devoted to matching for offset reduction is thereby optimized. These four transistors are made as large as practical in size to achieve a low offset, and will be limited only by the total area available and the minimum speed at which the amplifier should operate.

A further finding relevant to the present invention is that transistor absolute area determines important circuit properties. Transistor designers are accustomed to thinking of design in terms of aspect ratio (the ratio of width to length) as the principle determinant of circuit properties, and area as mainly a determinant of parasitic capacitance. With the prevailing view, it seemed difficult to maintain the scaled matching of the output stage if the input stage transistors were made very large. However, the actual state of affairs is that as the input transistors are made larger, the scaled matching to the output stage becomes less of a factor, and only the input transistors determine the effective amplifier offset. An additional benefit is that amplifier gain increases as the input transistors are made larger.

By eliminating the criticality of scaled matching, the only components that must be precisely matched are pairs of transistors. Pairs of transistors can be easily placed together in a standard layout cell of convenient size, such that critical matching is not required between layout cells. This allows cells to be placed into a physical chip design by an automatic place and route mechanism. Since switching techniques are not used to produce low offset, routing of connections is not critical and is also compatible with an automatic place and route mechanism. Use of automatic place and route along with a more compact precision (low offset) operational amplifier allows rapid low cost design of custom circuit configurations that contain many operational amplifiers, such as multi-channel signal conditioning or filtering circuits.

A second aspect of the embodiment shown in FIG. 2 is that the output stage transistors are made smaller than was considered feasible in prior art. This follows from their reduced importance in matching for offset reduction according to the principle of larger input transistors being dominant in matching effects. The output transistors can be made with short channels, normally not considered good for matching. Because the channels are short, for a given aspect ratio these transistors can be much smaller. Because they are smaller, the output stage transistors have lower parasitic capacitance, allowing the amplifier to operate faster. The output stage transistors may even be made with the shortest channel length attainable in the process technology with which they are fabricated, which makes them much more compact and faster than would ordinarily be considered practical in the design of static precision operational amplifiers. The increase in speed of the output stage permits the stability compensation circuit 205 to be smaller than expected.

FIG. 2 shows an amplifier design in which the input differential pair 202 is comprised of P-type field effect transistors (FET's), and the associated current mirror 203 is comprised of N-type FET's. This arrangement has good speed performance properties since the current mirror, which limits speed performance, uses the higher mobility N-type charge carriers. The selection shown for P- and N-type FET's is in no way intended to limit the invention to this configuration. Skilled practitioners will see that the principles as outlined in this specification and the claims can easily be applied to amplifiers with N-type differential pairs or a mix of N- and P-type differential pairs in the input circuits.

Gain and Stability Compensation

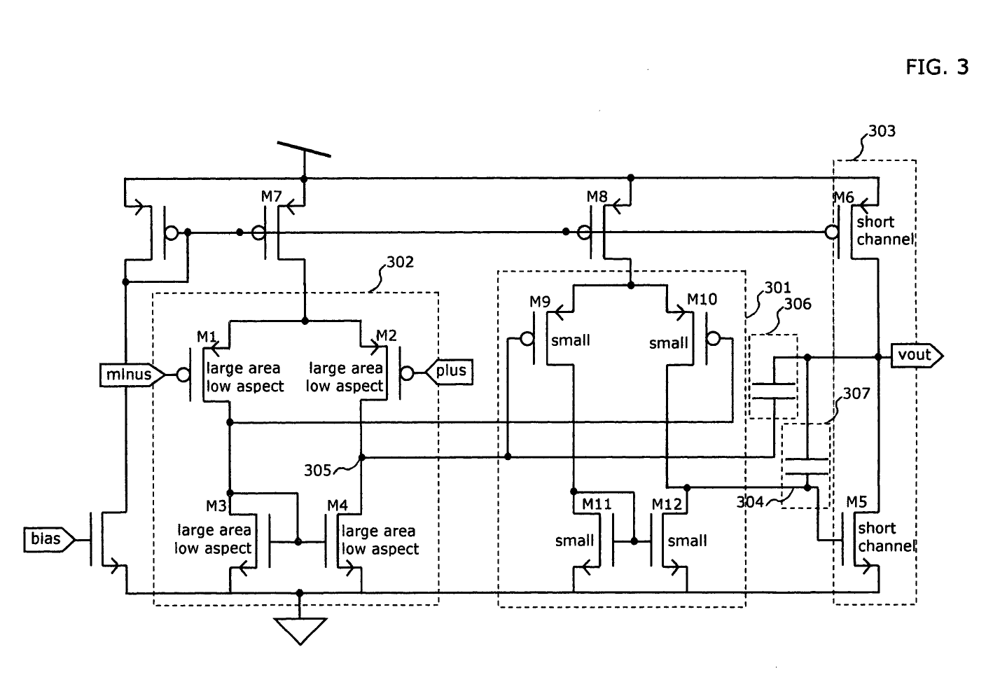

Turning next to FIG. 3, there is shown a three-stage low offset operational amplifier in accordance with the present invention. This embodiment is produced from the one shown in FIG. 2 by adding a differential gain stage 301 comprised of relatively small, fast transistors. The gain stage transistors can be made small without adversely affecting offset matching because the large input stage transistors 302 dominate in the determination of offset. It should be noted that the third or output stage 303 can be any type of output stage as long as it has an inverting input, and is not limited to the simple class A arrangement shown. An inverting input 304 is necessary for Miller compensation as described below. The present invention does not particularly concern itself with the output stage, except to note that its role in offset determination is lessened, thereby increasing flexibility in its design.

Stability compensation for three stage high gain amplifiers can be difficult and even impossible because of the large number of frequency response poles that must be considered, often spaced closely together so that they produce more than ninety degrees of phase shift at frequencies where the gain of the amplifier is still greater than one. Even if the amplifier can be stabilized, the value of Miller capacitance required might be impractically large. These difficulties are resolved in the embodiment shown in FIG. 3 by the use of a nested Miller compensation technique. A small compensation circuit consisting of a Miller capacitor or similar arrangement, such as a Miller capacitor in series with a resistor, is placed around the output stage by connecting the compensation circuit between the amplifier output at node vout, and the (inverting) input to the output stage at node 304. By keeping the compensation small the phase shift of the output stage begins at a very high frequency, which is helpful in the compensation of the rest of the amplifier. The output stage must be able to operate at high speed in order to keep the compensation small and maintain a high frequency for its lowest response pole.

Compensation must be applied to earlier stages so that the resultant attenuation of response will have attenuated the amplifier gain below one before the frequencies of the compensated output stage are reached. Therefore the compensated frequency response pole of the remainder of the amplifier must be at a much lower frequency than the output stage compensated response. The compensated frequency response pole is given by ½πRCG where C is the value of the Miller capacitor, G is the gain between the input and output nodes, and R is the impedance at the input node where the compensation network is connected.

If compensation were used around a single stage, for example around the central gain stage, an impractically large Miller capacitor might be required. If compensation is used around the entire amplifier, this affects its input impedance, which should remain as high as possible. The solution is to place a second compensation circuit around the final two stages, connecting from the output node vout to the inverting input to the gain stage 305. There are two important effects that reduce the value of Miller capacitor required in this configuration and make the technique practical. First, the high gain of the two stages across which the compensation circuit is placed increases the effectiveness of the Miller capacitor by the amount of that gain (G). Second, the use of very large and low aspect ratio transistors in the input stage 302 keeps the impedance (R) at node 305 very high. Often the value of Miller capacitor required to stabilize a three stage amplifier by this method is no greater than that required to stabilize a two stage amplifier of ordinary design.

Rail-To-Rail for Low Offset

Amplifiers with a single differential input pair as shown in FIG. 2 have a limitation of input common mode range. FET threshold voltage is the nominal source to gate voltage at which a FET device begins to conduct current and operate normally, usually about 0.7 volts. Because of this, the voltage at node 207 will normally be one threshold above the lowest of the voltages at nodes plus or minus. As the value of both the plus and minus inputs rise to within about 0.7 volts of the positive supply rail, the voltage at node 207 rises to the supply rail, and the bias transistor M7 has zero volts from source to drain and ceases to conduct current. It is said to “pinch off.” With no current flowing through the input circuit, the amplifier ceases to operate.

As previously described, methods exist for designing amplifiers which overcome common mode range limitations. Methods that use switching are not ideal for use with the present invention, because they decrease the advantages of compactness, low noise, simplicity and un-criticality of connection routing. Methods which use a combination of P-type and N-type input differential pairs with a crossover or blend point in the center of the common mode range are unsuitable without switching, because they introduce variability into the offset as the amplifier transitions from being controlled by one of the input pairs to the other.

Offset is most critical near the center of the common mode range, and it is most disadvantageous for it to have maximum variance there. Operational amplifiers are nearly always (except when used as a comparator) connected in feedback configurations such that the voltage at the minus input tracks the voltage at the plus input. When small signals are present, offset is most critical, because it appears relatively large compared to the small signal. It can be and usually is arranged that small signals are in the broad middle of the common mode range, not next to the supply rails. When large signals are present the full common mode range is used, but the relative importance of offset is correspondingly much less. Therefore if the offset blend points can be moved from the center to near the rails for a rail-to-rail amplifier design, its overall performance and suitability in precision circuits will be much greater.

The point at which an input circuit fails because of common mode range limitations can be moved by level shifting both inputs. If the voltages presented to a P-type differential pair are shifted down by 0.7 volts from the actual amplifier input voltages the input circuit will not pinch off as the common mode voltage approaches the positive supply rail, and vice versa for N-type differential pairs and the negative supply rail. A level shifting circuit thus inserted between the amplifier input and differential pair would need to be compact, fast enough that it would not disrupt the frequency stabilization of the amplifier, and would itself have to have a comparably low offset since a pair of level shifting circuits is required, one for the plus input and one for the minus.

Fortunately such level shifting circuits are available in the form of a FET connected in a source follower circuit. As previously described, the voltage at the source of a FET is approximately one threshold below (N-type) or above (P-type) the gate voltage. A FET of the same size as the input differential FET's will have about the same degree of offset matching, and will be suitable. It will preserve the input impedance of the FET amplifier since the input signal is still connected to the gate of just one FET. The problem remaining is to establish a bias current through the level shifting FET without disrupting its desirable characteristics.

Common methods of biasing a source follower circuit include placing a resistor or a resistor-connected FET in series with the source, and connecting the drain to the appropriate supply rail. The problem with a resistor is that in order to keep the bias current small for low power operation it must be very large. The matching of resistors in twin level shifting circuits may also introduce offset problems. The bias current in a resistor also varies with applied voltage, which introduces variability in the amount of the level shift. The problem with a resistor-connected FET is that it too must be quite a large device to provide low bias current, and the bias current will vary with applied voltage even more than a normal resistor. A preferable method of biasing the level shifter, though unusual in the context of a level shifter, is to simply use an ordinary bias transistor connected as a current source. To preserve geometric offset matching, it should be of the same size and aspect ratio as the differential pairs and the current mirrors used in the input circuit and the level shifter itself.

The technique of level shifting applied to a single input differential pair doesn't solve the problem of common mode range, but shows how it can be moved by small amounts. The method of applying level shifting to rail-to-rail low offset operational amplifier design will be described in connection with a preferred embodiment below.

Offset Modeling

The bias current through the level shifter is somewhat arbitrary, and should be selected to optimize one or both of two concerns. First, the bias current range can be selected to minimize offset. To determine this, an offset modeling method must be utilized. One method is to assume that geometric variations will be of the order of one quarter of the minimum feature size of the fabrication process. A computational (spice) model of the level shifter circuit can be constructed and the level shift response as bias transistor feature size is varied by this small amount can be determined.

Second, the bias current range must be compatible with the intended total power consumption of the amplifier. Using the computational model described above, the bias current can be varied over several points in the compatible power range, and the value which has the least effect on level shifter offset can be chosen. As it turns out, the level shifter offset variability can usually be constrained by this method to be of the same order as the offset due to variability in the amplifier input circuit, so that no significant increase in offset is caused by the level shift circuit.

### Preferred Embodiment

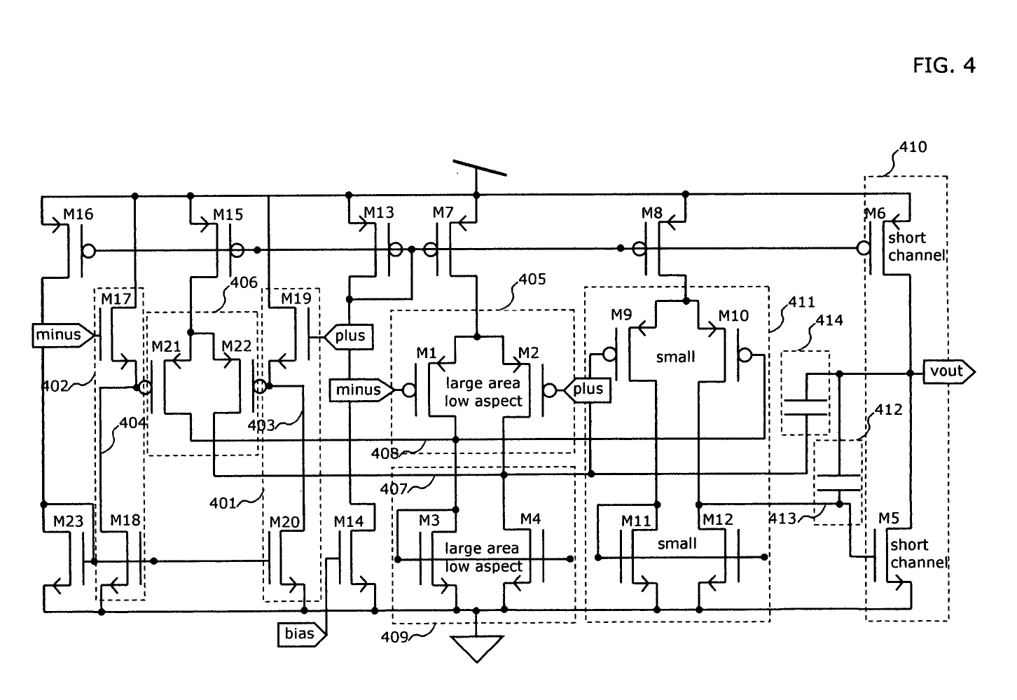

Turning to FIG. 4 there is shown the preferred embodiment of the present invention. A differential input voltage level shift circuit is provided in two parts 401 to shift the plus input and 402 to shift the minus input. The inputs plus and minus are connected to a first input stage differential pair 405 and to the level shift circuit. The shifted input voltages appearing at the outputs of the level shift circuit on nodes 403 and 404 are connected to a second input stage differential pair 406 which is of the same type P or N as the first input differential pair, and will usually be identical. The differential outputs from the two input differential pairs are recombined by simple current summation at nodes 407 and 408, which are also connected to the single input stage current mirror 409.

While FIG. 4 shows P-type differential pairs, the skilled practitioner easily recognizes the same design principles apply to an amplifier made with N-type pairs, or to an amplifier using bipolar junction or other non-FET devices. The differential output nodes 407 and 408 may be connected to a variety of further circuits to complete the amplifier in the usual manner, or node 407 may be taken as a single ended output for further use.

While a variety of types of level shifting circuit could be used, the one shown in FIG. 4 consists of level shifting FET's M17 and M19 connected in series with bias FET's M18 and M20. And while the only firm constraint on transistor sizing is that the pairs be well matched M17 with M19, M18 with M20, M21 with M22, M1 with M2 and M3 with M4, it is recommended that for optimization of offset all the aforementioned matched pairs be about the same size, that they be large, and have an aspect ratio of about one.

As shown in FIG. 4 the preferred embodiment has an output stage 410 so that the circuit can be used as an operational amplifier. A very simple output stage is shown. The skilled practitioner will recognize that a variety of output stages are possible, and that the principle of dominating offset determination with large input transistors increases the flexibility in output stage design.

FIG. 4 also shows a gain stage 411 so that the operational amplifier has high gain, a first compensation circuit 412 connected from the output node vout to the input of the output stage node 413, and a second compensation circuit 414 connected from vout to node 407. These compensation circuits may comprise a simple Miller capacitor. Skilled practitioners will recognize other possibilities such as a capacitor with a series resistor.

Skilled practitioners will also recognize that the bias currents for the circuit are set by distributing a voltage named bias for which the relationship between bias and the current through M14 is known. This current is mirrored and scaled by M7, M8, M13, M15, M16 and M23 to provide appropriate bias currents for the various amplifier stages that satisfy tradeoffs between power consumption and speed of operation. Because the amplifier of FIG. 4 uses low aspect ratio transistors, it is suitable for very low bias currents in the microamp range, and very low power operation. The transistors M7 and M15 providing bias for the differential input pairs can be extremely low aspect ratio (much less than one) and have long channels, consistent with a low bias current and also with very low variance of bias current as the common mode operating point varies. This decreases variance of offset with input common mode so that it is usually less than the offset due to transistor matching.

Performance Characteristics.

While typical industry estimates of static CMOS operational amplifier offset are around 5 millivolts, a sizing of the large input transistors of about 20 times the minimum feature size (or about 40 lambda) when used in accordance with the present invention produces amplifiers with typical offsets of around 0.1 millivolts (100 microvolts) and usually not worse than 0.5 millivolts, an order of magnitude improvement. This size is convenient for use in cell libraries for automatic routing. Bandwidth of such an amplifier is acceptable for most instrumentation applications. Larger transistor sizing produces even lower offset, while smaller sizing produces higher offset and higher bandwidth. The skilled practitioner recognizes that bandwidth is also influenced by bias current and other factors of circuit and fabrication process.

Instead of one offset transition point near the center of the common mode range as most rail-to-rail amplifiers relying on mixed P- and N-input pairs will have, the amplifier of FIG. 4 has two transition points. These are each one threshold voltage (usually about 0.7 volts) from the supply rails. In the broad center of the common mode region, the offset is an average of the offset produced by each of the two input circuits. When both inputs are within one threshold of the negative supply rail, the level shifter bias transistors M18 and M20 pinch off and the amplifier offset shifts to a value determined only by the first input differential pair and the input current mirror. When both inputs are within one threshold of the positive supply rail, the first differential pair bias transistor M7 pinches off and the offset is determined by the second differential pair together with the current mirror and level shifters.

Use of the invention has been found to enable as much as double the number of low offset rail-to-rail operational amplifiers to be fabricated in a given circuit area as compared to prior static precision designs, with typical offset values of one third or less. The invention has also been found to enable the design of very high gain instrumentation amplifiers, because of the low offset, but with power consumption an order of magnitude less than switching designs. Noise figures of amplifiers made according to the invention are also competitive with other techniques, since while the input FET's may be large, the very low bias current which is possible minimizes flicker noise.

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

What is claimed is:

1. A low offset operational amplifier comprising:
a first stage differential input circuit having low aspect ratio devices of size chosen to achieve a low offset voltage;
an output stage having short channel high aspect ratio devices able to operate at higher speed than the input stage;
whereby said operational amplifier will have low offset and a small compensation circuit.

2. The operational amplifier of claim 1 wherein said first stage differential input circuit is made of field effect transistors.

3. The operational amplifier of claim 2 wherein said first stage differential input circuit is made of transistors with aspect ratio of about one.

4. The operational amplifier of claim 1 with the addition of a gain stage between the input circuit and the output stage;
whereby said operational amplifier will have very high gain.

5. The operational amplifier of claim 4 wherein said gain stage is made of small devices able to operate at higher speed than the input stage.

6. The operational amplifier of claim 4 with the addition of a stability compensation circuit comprising:
a first compensation circuit connected from the output of the amplifier to an inverting input of the output stage;
a second compensation circuit connected from the output of the amplifier to an inverting input of the gain stage;
whereby amplifier stability is achieved with small compensation circuit elements.

7. A three stage operational amplifier with nested miller compensation comprising:
a first stage differential input circuit;
a second stage differential gain circuit;
a third stage inverting output circuit;
a first compensation circuit connected from the output of the amplifier to the input of the third stage;
a second compensation circuit connected from the output of the amplifier to the inverting input of the second stage;
whereby stability of the high gain amplifier is achieved with low area compensation circuit elements.

8. A rail-to-rail input common mode range amplifier comprising:
an input voltage level shifting circuit;
a first input stage differential pair;
a second input stage differential pair of the same device type as the first input stage differential pair;
a single input stage current mirror;
whereby operation over a rail-to-rail input common mode range is obtained without bias elevation above a rail, an offset discontinuity in the center of the common mode range, or complex recombination circuitry.

9. The amplifier of claim 8 wherein said input voltage level shifting circuit comprises two matched pairs of series connected field effect transistors;
whereby the static bias current and circuit area are minimized.

10. The amplifier of claim 9 wherein said input voltage level shifting circuit and first input stage differential pair and second input stage differential pair and input stage current mirror are comprised of transistors all about the same size;
whereby the contribution of any one of them to amplifier offset is about the same, and total circuit area for a desired offset is optimized.

11. The amplifier of claim 10 wherein said input voltage level shifting circuit and first input stage differential pair and second input stage differential pair and input stage current mirror are comprised of transistors all of aspect ratio of about one;
whereby the contribution of length and width of transistors to the amplifier offset is about the same, and total circuit area for a desired offset is optimized.

12. The amplifier of claim 11 with the addition of an output stage;
whereby the amplifier can be used as an operational amplifier.

13. The amplifier of claim 12 with the addition of a gain stage;
whereby the gain of the operational amplifier is very high;

14. The amplifier of claim 13 with the addition of:
a first compensation circuit connected from the output of the amplifier to the input of the output stage;
a second compensation circuit connected from the output of the amplifier to an input of the gain stage;
whereby stability of the amplifier is achieved with a small compensation circuit.
